(19) United States
(12) Patent Application Publication
(10) Pub. No.: US 2026/0156989 A1
(43) Pub. Date: Jun. 4, 2026

(54) A METHOD FOR MANUFACTURING AN OPTOELECTRONIC SEMICONDUCTOR DEVICE AND AN OPTOELECTRONIC SEMICONDUCTOR DEVICE

(71) Applicant: ams-OSRAM International GmbH, Regensburg (DE)

(72) Inventors: Reiner Windisch, Pettendorf (DE); Peter Brick, Regensburg (DE)

(21) Appl. No.: 19/126,568

(22) PCT Filed: Nov. 8, 2023
(86) PCT No.: PCT/EP2023/081203

§ 371 Date: May 1, 2025

(30) Foreign Application Priority Data
Nov. 10, 2022 (DE) 10 2022 129 759.4

(51) Int. Cl. H10H 20/80; H10H 20/01

(52) U.S. Cl. CPC H10H 20/872; H10H 20/01335; H10H 20/019

(57) ABSTRACT

In an embodiment a method includes patterning a masking material over a growth substrate, epitaxially growing a first semiconductor material over exposed surface regions, wherein pillars are formed in a region facing the growth substrate, and a contiguous first semiconductor layer of a first conductivity type is formed in a region facing away from the growth substrate, forming an active region over the first semiconductor layer and the pillars, epitaxially growing a second semiconductor layer of a second conductivity type over the active region, applying a carrier substrate over the second semiconductor layer, and detaching the growth substrate such that the pillars are arranged in the region of a first main surface of a resulting workpiece, wherein a modal value M(d) of a distance d between centers of the exposed regions satisfies the following condition: M(d)≤1.5*λ, and wherein λ denotes an average wavelength of the electromagnetic radiation in the first semiconductor material.

### CROSS-REFERENCE TO RELATED APPLICATIONS

This patent application is a national phase filing under section 371 of PCT/EP2023/081203, filed Nov. 8, 2023, which claims the priority of German patent application no. 10 2022 129 759.4, filed Nov. 10, 2022, each of which is incorporated herein by reference in its entirety.

### TECHNICAL FIELD

Light emitting diodes (“LEDs”) are semiconductor devices including a semiconductor layer stack comprising a sequence of a first semiconductor layer of a first conductivity type, for example n-type, and a second semiconductor layer of a second conductivity type, for example p-type. When a voltage is applied to the semiconductor layer stack, photons are emitted due to the recombination of electrons and holes. In general, an LED represents a Lambertian emitter that emits electromagnetic radiation via a main surface of the semiconductor layer stack. The intensity of the emitted electromagnetic radiation changes depending on an emission angle.

### BACKGROUND

For many applications, a punctiform light source having the smallest possible dimensions in the μm range is desired. Therefore, concepts are developed by means of which improved optoelectronic semiconductor devices can be produced.

### SUMMARY

Embodiments provide an improved method for producing an optoelectronic semiconductor device as well as an improved optoelectronic semiconductor device.

A method for manufacturing an optoelectronic semiconductor device comprises patterning a masking material over a growth substrate such that a pattern of exposed surface regions is generated, and epitaxially growing a first semiconductor layer of a first conductivity type over the exposed surface regions, wherein pillars are formed in a region facing the growth substrate, and a contiguous first semiconductor layer of a first conductivity type is formed in a region facing away from the growth substrate. The method further comprises forming an active region over the first semiconductor layer and the pillars, wherein the active region is adapted to emit or absorb electromagnetic radiation, and epitaxially growing a second semiconductor layer of a second conductivity type over the active region. A modal value M(d) of a distance d between centers of the exposed regions satisfies the following condition: M(d)≤1.5*λ, wherein λ denotes the average wavelength of the electromagnetic radiation in the first semiconductor material.

The term “modal value” used in the present disclosure denotes a most frequently occurring value within the existing distances between the centers. For example, the following relationship can apply to the modal value M(d) of the distance: 0.4*λ≤M(d)≤0.6*λ.

The semiconductor material may contain InGaN, for example. For example, an In content of the semiconductor material may increase with increasing distance from the growth substrate. For example, a refractive index of InGaN may lie in a range from 2.2 to 2.4, a refractive index of AlN may lie in a range from 2.0 to 2.2, depending on the production method. Accordingly, taking into account this refractive index range, the following relationship can apply to the modal value M(d) of the distance: M(d)<0.625*λ′ or

0.16*M(d)≤λ′≤0.3*M(d), wherein λ′ denotes the wavelength in vacuum.

The term “average wavelength in a semiconductor material” relates to an effective wavelength averaged over different refractive indices. The effective wavelength depends on a refractive index in the propagation medium. If the refractive index changes due to a spatially changing composition ratio, averaging takes place over the different refractive indices or the different effective wavelengths.

According to embodiments, the first semiconductor material can be grown such that a refractive index of the first semiconductor material is changed. For example, the refractive index of the first semiconductor material may change periodically. A period p within which the refractive index changes periodically may satisfy the following relationship: 0.4*λ≤p≤0.6*λ, wherein λ corresponds to the wavelength within the first semiconductor material.

For example, the first semiconductor material may be doped with dopants of a first conductivity type. According to further embodiments, the first semiconductor material may be undoped in the region in which pillars are formed, and may be doped with dopants of the first conductivity type in the region in which the contiguous first semiconductor layer is formed.

According to embodiments, the method may further comprise applying a carrier substrate over the second semiconductor layer and detaching the growth substrate such that the pillars are arranged in the region of a first main surface of a resulting component or workpiece.

The pillars may be removed from a part of the optoelectronic semiconductor device. For example, the pillars may be removed from a region of the optoelectronic semiconductor device that does not horizontally overlap with the active region. For example, the pillars may be removed from the entire region or from a part of the region of the optoelectronic semiconductor device that does not horizontally overlap with the active region.

According to further embodiments, the pillars may be removed from a region of the optoelectronic semiconductor device that horizontally overlaps with the active region. For example, the pillars may be removed from the entire region or from a part of the region of the optoelectronic semiconductor device that horizontally overlaps with the active region.

The method may further comprise forming a first contact element in a region from which the pillars have been removed. For example, the pillars may be formed undoped here.

Furthermore, the method may comprise applying a contact layer of the first conductivity type over the growth substrate, wherein the masking layer is applied over the contact layer and the first semiconductor material of the first conductivity type is grown over the contact layer. For example, the first semiconductor material may be doped here.

For example, the growth substrate may be detached after applying the carrier substrate over the second semiconductor layer, further at least a part of the contact layer may be removed after detaching the growth substrate.

According to embodiments, an optoelectronic semiconductor device comprises a first semiconductor layer of a first conductivity type, a second semiconductor layer of a second conductivity type, and an active region, which is adapted to emit electromagnetic radiation, between the first and the second semiconductor layer, wherein the first semiconductor layer, the active region and the second semiconductor layer are arranged forming a semiconductor layer stack and the active region is adjacent to a second main surface of the first semiconductor layer. The optoelectronic semiconductor device further comprises an ordered photonic structure over a first main surface of the first semiconductor layer, wherein the ordered photonic structure is directly adjacent to the first semiconductor layer, is arranged over the active region and comprises pillars containing a material of the first semiconductor layer. A modal value M(d) of a distance d between centers of the pillars satisfies the following condition: M(d)≤1.5*λ, wherein λ denotes the wavelength of the electromagnetic radiation in the first semiconductor layer.

For example, the following condition can be satisfied:

$$0.4 * λ \leq M ( d ) \leq 0.6 * λ .$$

For example, a semiconductor material of the first semiconductor layer may contain InGaN. An In content of the semiconductor material of the pillars may decrease with increasing distance from the first semiconductor layer.

Furthermore, a defect density within the pillars may increase with increasing distance from the first semiconductor layer.

For example, the pillars may be removed from a part of the optoelectronic semiconductor device.

For example, a part of the optoelectronic semiconductor device in which pillars are present may be smaller than a horizontal extension of the active region.

The optoelectronic semiconductor device may further comprise a first contact element electrically connected to the first semiconductor layer, wherein the first contact element is arranged in the part of the optoelectronic semiconductor device from which the pillars are removed.

### BRIEF DESCRIPTION OF THE DRAWINGS

The accompanying drawings serve to understand embodiments of the invention. The drawings illustrate embodiments and together with the description serve to explain them. Further embodiments and numerous of the intended advantages emerge directly from the following detailed description. The elements and structures shown in the drawings are not necessarily illustrated true to scale with respect to one another. Identical reference signs refer to identical or mutually corresponding elements and structures.

FIGS. 1A to 1C illustrate steps for producing an optoelectronic semiconductor device;

FIGS. 2A to 2C illustrate further steps for producing a semiconductor device;

FIG. 2D shows a semiconductor device according to embodiments;

FIG. 3 shows components of an optoelectronic semiconductor device according to further embodiments;

FIG. 4 shows components of an optoelectronic semiconductor device according to further embodiments;

FIG. 5 shows components of an optoelectronic semiconductor device according to further embodiments;

FIG. 6A shows a cross-sectional view of an optoelectronic semiconductor device according to embodiments;

FIG. 6B shows a plan view of the optoelectronic semiconductor device shown in FIG. 6A;

FIG. 6C shows an arrangement of semiconductor devices according to embodiments;

FIG. 7 shows a schematic view of an electrical component according to embodiments; and

FIG. 8 summarizes a method according to embodiments.

### DETAILED DESCRIPTION OF ILLUSTRATIVE EMBODIMENTS

In the following detailed description, reference is made to the accompanying drawings, which form part of the disclosure and in which specific embodiments are shown for illustrative purposes. In this context, directional terminology such as “top”, “bottom”, “front”, “back”, “over”, “on”, “in front”, “behind”, “leading”, “trailing”, etc. is referred to the orientation of the figures just described. Since the components of embodiments can be positioned in different orientations, the directional terminology serves only for explanation and is in no way restrictive.

The description of the embodiments is not restrictive since other embodiments also exist and structural or logical changes can be made without deviating from the scope defined by the claims. In particular, elements of embodiments described below can be combined with elements of other embodiments described unless the context indicates otherwise.

The terms “wafer” or “semiconductor substrate” used in the following description can comprise any semiconductor-based structure having a semiconductor surface. Wafer and structure should be understood to include doped and undoped semiconductors, epitaxial semiconductor layers, optionally supported by a base support, and further semiconductor structures. For example, a layer of a first semiconductor material may be grown on a growth substrate of a second semiconductor material, for example a GaAs substrate, a GaN substrate or a Si substrate, or of an insulating material, for example on a sapphire substrate.

Depending on the intended use, the semiconductor may be based on a direct or an indirect semiconductor material. Examples of semiconductor materials particularly suitable for generating electromagnetic radiation comprise, in particular, nitride semiconductor compounds by which, for example, ultraviolet, blue or longer-wave light can be generated, such as, for example, GaN, InGaN, AlN, AlGaN, AlGaInN, AlGaInBN, phosphide semiconductor compounds by which, for example, green or longer-wave light can be generated, such as, for example, GaAsP, AlGaInP, GaP, AlGaP, and further semiconductor materials such as GaAs, AlGaAs, InGaAs, AlInGaAs, SiC, ZnSe, ZnO, Ga₂O₃, diamond, hexagonal BN and combinations of said materials. The stoichiometric ratio of the compound semiconductor materials may vary. Further examples of semiconductor materials may comprise silicon, silicon-germanium and germanium. In the context of the present description, the term “semiconductor” also includes organic semiconductor materials.

The term “substrate” generally comprises insulating, conductive or semiconductor substrates.

The term “vertical” as used in this description is intended to describe an orientation which is substantially perpendicular to the first surface of a substrate or semiconductor body. The vertical direction may correspond, for example, to a growth direction during the growth of layers.

The terms “lateral” and “horizontal” as used in this description are intended to describe an orientation or orientation which is substantially parallel to a first surface of a substrate or semiconductor body. This may be, for example, the surface of a wafer or a chip (die).

The horizontal direction may lie, for example, in a plane perpendicular to a growth direction during the growth of layers.

The term “pillar” used in the context of the present disclosure denotes a structure having any, for example round, oval or angular, cross-section extending in a vertical direction. It is intended that the diameter of a pillar changes only insignificantly along the vertical direction. For example, a difference between the maximum and the minimum diameter of a pillar is smaller than a minimum diameter of a pillar.

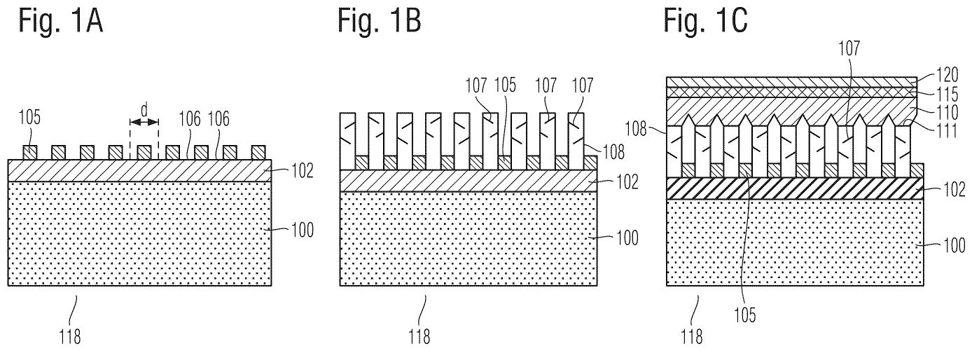

As illustrated in FIG. 1A, a patterned masking layer 105 is generated over a suitable growth substrate 100, which may be, for example, a silicon substrate or a sapphire substrate. For example, as illustrated in FIG. 1A, first a contact layer, for example an n-doped contact layer 102, may be applied over the growth substrate 100, for example in direct contact with the growth substrate 100. According to embodiments, the contact layer 102 may be an InGaN contact layer.

Then a masking layer, for example of silicon oxide or silicon nitride, is formed and patterned. For example, the patterning may comprise a photolithographic method, for example using a stepper or electron beam lithography. For example, a region-wise regular, for example hexagonal, pattern of, for example, round holes can be generated in the masking layer by the patterning. For example, the masking layer may furthermore be patterned by etching. As a result, a patterned masking material 105 is formed, wherein a pattern of exposed surface regions 106 is generated. The exposed surface regions 106 are not covered with the masking material 105.

For example, in a case as in FIG. 1A, in which an n-contact layer is provided, surface regions of the n-contact layer 102 may be exposed. The centers of the exposed regions 106 may, for example, have a distance d.

Thereafter, a first semiconductor material is epitaxially grown over the exposed surface regions 106. In this case, as shown in FIG. 1B, pillars 108 are formed. According to embodiments, a material of the first semiconductor layer may be InGaN. In order to achieve a desired wavelength range of the emitted electromagnetic radiation, during the growth of the first semiconductor layer, the In-concentration is, for example, gradually increased in order to finally achieve the desired in-concentration in the first semiconductor layer to be subsequently grown. Due to lattice mismatches, defects 107 are formed which grow out to the side of the resulting pillars 108. This is indicated in FIG. 1B. For example, according to the embodiments described in the context of the present application, a diameter of the pillars may be smaller than (0.75*d) or smaller than (0.5*d), wherein d corresponds to the distance between pillar centers. Thereafter, the growth conditions are changed so that after a low defect density is achieved, a coalescing of the pillars is brought about and a continuous first semiconductor layer 110 is formed.

For example, the first semiconductor material may be doped with dopants of a first conductivity type, for example n-type. According to further embodiments, the first semiconductor material may be undoped in a region in which the pillars 108 are formed. In the region in which the continuous first semiconductor layer 110 is formed, the first semiconductor material may be doped with dopants of the first conductivity type.

For example, the resulting first semiconductor layer 110 may be an InₓGa₁₋ₓN layer with a high In content. For example, x may be greater than 0.3. For example, the pillars 108 may be applied such that the region in which the pillars are present has a layer thickness of at least 0.5 μm. For example, a maximum thickness of the region in which the pillars 108 are present may be 2 to 3 μm. In the layer region comprising coalesced pillars, the composition is selected such that a lattice constant is adapted to the lattice constant of the active region to be applied. In this way, the defect density may be minimized and the efficiency of the device may be increased.

As is furthermore illustrated in FIG. 1C, an active region 115 and a second semiconductor layer of a second conductivity type, for example p-type, may subsequently be formed above the active region 115. The material of the second semiconductor layer may also be InGaN, for example In_{y}Ga_{1-y}N.

The active region may comprise, for example, a pn-junction, a double heterostructure, a single quantum well structure (SQW) or a multiple quantum well structure (MQW) for generating radiation. The term “quantum well structure” here does not have any significance with regard to the dimensionality of the quantization. It thus comprises, inter alia, quantum wells, quantum wires and quantum dots and also any combination of these layers.

In the method described, a modal value M(d) of a distance d between the centers of the exposed regions 106 may satisfy the following condition: M(d)<0.625*λ′, or 0.16*λ′≤M(d)≤0.5*\′ or 0.2*\′≤M(d)≤0.3*λ′, wherein λ′ denotes the wavelength of the electromagnetic radiation in vacuum.

FIG. 1C shows a cross-sectional view of a resulting workpiece 118.

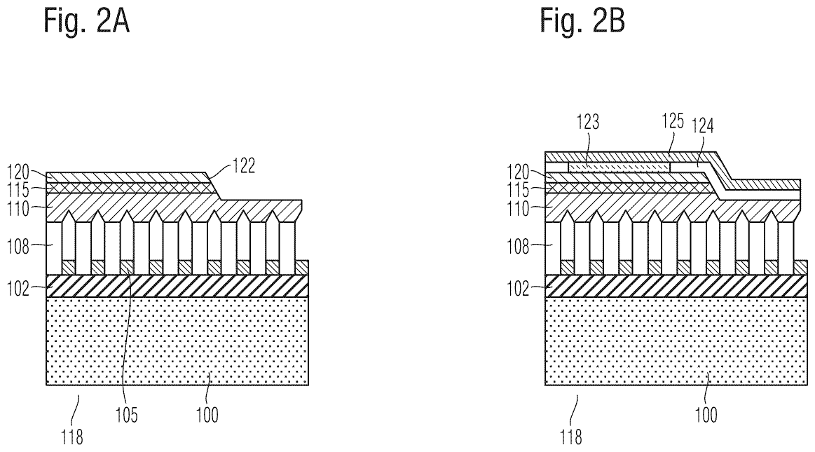

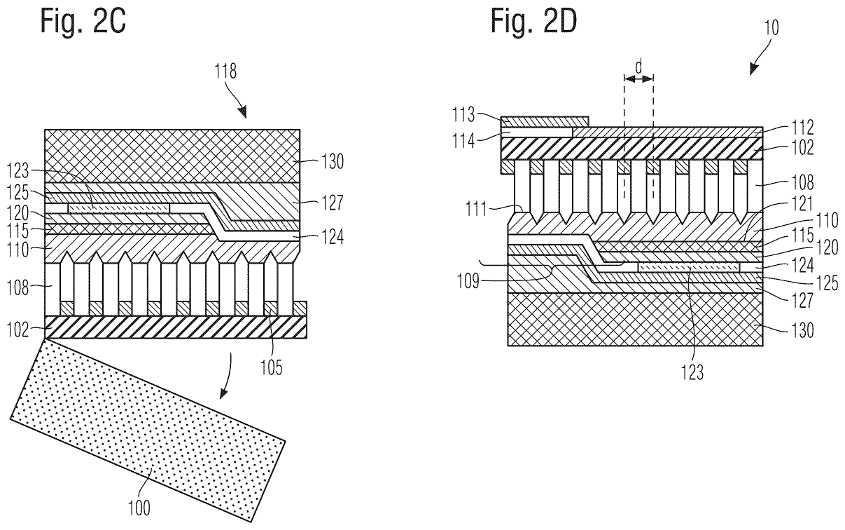

As illustrated in FIG. 2A, a mesa structure 122 may subsequently be defined, for example by etching. For example, a part of the active region 115 and a part of the second semiconductor layer 120 may be removed. As a result, a part of a surface of the first semiconductor layer 110 may be exposed.

Subsequently, as illustrated in FIG. 2B, a second contact region 123 may be applied and patterned. For example, a metal of the second contact region may have a high reflectivity. According to further embodiments, instead of a metal, a transparent conductive oxide (“ITO”, indium tin oxide, or “TCO”, transparent conductive oxide) or a combination of such an oxide and a metal may also be used. Furthermore, an insulation layer 124, for example an insulating oxide or silicon nitride, may be applied. Subsequently, a continuous mirror layer 125 may be formed. The mirror layer 125 may, for example, cover a part of the first semiconductor layer 110, a side flank of the mesa 122, and the second contact region 123 and the second semiconductor layer 120. A material of the mirror layer may, for example, have a high reflectivity and may comprise gold, silver or aluminum. The mirror layer may comprise further layers for bonding to a following solder layer. FIG. 2B shows a cross-sectional view of a resulting workpiece 118.

Thereafter, the workpiece 118 may, for example, be applied to a carrier substrate 130 via a suitable solder material 127 and soldered. Alternatively, instead of the solder material 127, an electrically conductive adhesive may also be used. After bonding to the carrier substrate 130, the growth substrate 100 may be removed, for example, by a laser lift-off method. FIG. 2C illustrates this method step.

After turning the workpiece 118, a first contact region 112 may be formed. For example, an emission of the generated electromagnetic radiation may take place via the first contact region 112. Accordingly, the first contact region 112 may be formed as a transparent contact region. The transparent first contact region 112 may, for example, comprise a transparent oxide, optionally in combination with a very thin metal layer or a metal layer formed as non-contiguous very small metallizations, and have a transmittance of at least 50%. As is furthermore shown in FIG. 2D, an insulation layer 114 may be attached under a first contact element 113 for connection to a current source. An injection of charge carriers into a region outside the active region of the optoelectronic semiconductor device 10 is prevented or reduced by the insulation layer 114. FIG. 2D shows a cross-sectional view of an example of a correspondingly produced optoelectronic semiconductor device 10.

FIG. 2D shows a schematic cross-sectional view of an optoelectronic semiconductor device 10 according to embodiments. The optoelectronic semiconductor device 10 comprises a semiconductor layer stack comprising a first semiconductor layer 110 of a first conductivity type, for example n-type, a second semiconductor layer 120 of a second conductivity type, for example p-type, and an active region 115. The active region 115 is adapted to emit electromagnetic radiation. The active region 115 is arranged between the first and the second semiconductor layer 110, 120. The active region 115 is adjacent to a second main surface 121 of the first semiconductor layer 110. An ordered photonic structure 109 is arranged over a first main surface 111 of the first semiconductor layer 110. The ordered photonic structure 109 is directly adjacent to the first semiconductor layer 110 and is arranged over the active region 115. The ordered photonic structure comprises pillars 108 containing a material of the first semiconductor layer 110. A modal value M(d) of a distance d between centers of the pillars 108 satisfies the following condition:

$$M ( d ) < 1.5 * λ or$$

$$0.4 * λ \leq M ( d ) \leq 0.6 * λ ,$$

wherein λ denotes the wavelength of the electromagnetic radiation emitted by the active region 115 in the semiconductor material. Furthermore, according to the embodiments described in the context of the present application, a diameter of the pillars 108 may be smaller than (0.75*d) or smaller than (0.5*d).

Furthermore, according to the embodiments described in the context of the present application, a height of the pillars, i.e. for example a distance between the adjacent horizontal surface regions of the adjacent semiconductor layers, for example the first semiconductor layer 110 and the first conductivity type semiconductor contact layer 102, may be greater than 200 nm, for example greater than 300 nm or greater than 500 nm. For example, at a distance greater than 200 nm, for example greater than 300 nm or greater than 500 nm over the continuously formed first semiconductor layer 110, the diameter of the pillars may be at least 25% or at least 50% of the distance d between adjacent pillars.

In the context of the present disclosure, the term “ordered photonic structure” means a structure whose structure elements are arranged at predetermined locations. The arrangement pattern of the structure elements is subject to a specific order. The functionality of the ordered photonic structure results via the arrangement of the structure elements. The structure elements are arranged for example such that diffraction effects occur. The structure elements may be arranged for example periodically such that a photonic crystal is realized. According to further embodiments, the structure elements may also be arranged such that they represent deterministic aperiodic structures, for example bird spirals. According to further embodiments, the structure elements may also be arranged such that they realize a quasi-periodic crystal, for example an Archimedes lattice. According to further embodiments, the term “ordered photonic structure” also comprises periodic structures having larger periods such that, for example, a complete photonic band gap is not achieved. Such periodic structures may still have usable influences on the light propagation.

The ordered photonic structure 109 is arranged over the active region 115. More precisely, the ordered photonic structure 109 is arranged along a vertical emission direction of electromagnetic radiation. Correspondingly, the ordered photonic structure 109 overlaps with the active region 115 in the horizontal direction. As can furthermore be seen in FIG. 2D, the ordered photonic structure 109 is arranged over a first main surface of the first semiconductor layer 110. The first main surface 111 may have depressions. These depressions may be caused, for example, by overgrowth of the pillars 108 during the epitaxy method. The ordered photonic structure 109 or the pillars 108 forming the ordered photonic structure 109 are directly adjacent to the first semiconductor layer 110. For example, the pillars 108 may have a similar or identical composition ratio and an identical or similar dopant concentration to the first semiconductor layer 110 in a region of the interface with the first semiconductor layer 110. However, the composition ratio and the dopant concentration may also be different. For example, the pillars 108 may be doped with dopants of the first conductivity type.

For example, the semiconductor material may contain InGaN. For example, an In content of the semiconductor material within the pillars 108 may decrease with increasing distance from the first semiconductor layer 110. A first contact region 112 may be arranged adjacent to the contact layer 102 or to the ordered photonic structure and connected thereto. A second contact region 123 may be arranged adjacent to the second semiconductor layer 120. The second contact region 123 is electrically connected to the second semiconductor layer 120.

When an electrical voltage is applied between the first contact region 112 and the second contact region 123, current flows through the active zone 115, thereby generating electromagnetic radiation corresponding to the band gap of the active zone 115. The periodically arranged pillars 108 form an ordered photonic structure 109 and, according to embodiments, modify the optical modes within the waveguide structure formed by the first and second semiconductor layers 110, 120 and the active zone 115. The modification is, for example, such that the light generation in laterally guided modes is suppressed and the light generation in free-beam modes, i.e. modes which can be coupled out and propagate substantially vertically, is increased. According to further embodiments, the strength of the light generation in certain modes is only slightly influenced by the pillar structure 108. However, in this case, the pillar structure may provide for an efficient light coupling out of the generated light.

Due to the small layer thickness of the active layer, which corresponds to a maximum of some wavelengths of the emitted radiation, the number of modes may be limited. In this way, a selection of the free-beam modes coupled to the active region 115 is made possible. As a result, an improved directionality in comparison with a Lambertian emitter is made possible. The mechanisms described may occur depending on the selection of the respective layer thicknesses. For example, both mechanisms may also occur in parallel.

The optoelectronic semiconductor device 10 described may, for example, be a micro-LED (μLED) with an edge length of less than 10 μm, for example less than 5 μm. The edge length may, for example, be greater than 1 μm or 2 μm.

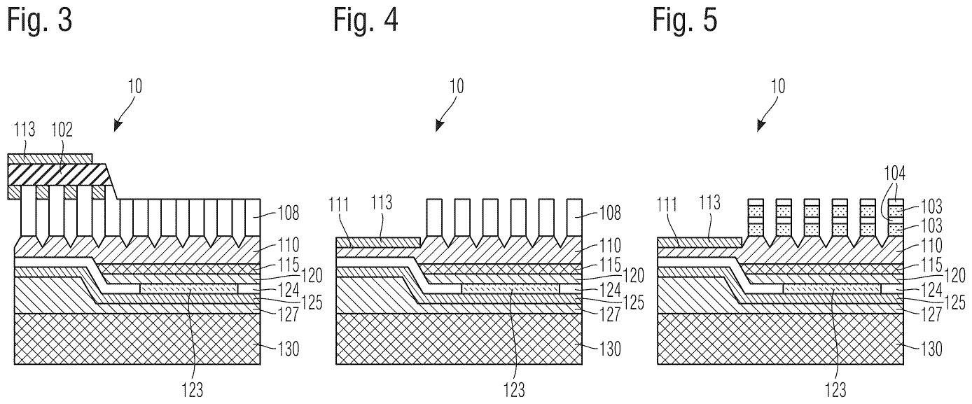

FIG. 3 shows a cross-sectional view of an optoelectronic semiconductor device according to further embodiments. The individual components in FIG. 3 are identical or similar to those shown in FIG. 2D. Deviating from the optoelectronic semiconductor device shown in FIG. 2D, the contact layer 102 is partially removed. The region from which the contact layer 102 is removed overlaps with the active region 115 in the horizontal direction. In the optoelectronic semiconductor device 10 shown, an improved light outcoupling may be achieved since it is possible that no optical losses occur due to absorption in the contact layer 102 or due to unintentional coupling into the waveguide formed by a continuous n-contact layer 102. As is furthermore shown in FIG. 3, the contacting is effected laterally here. This means that the first contact element 113 is arranged in a region that only slightly horizontally overlaps with the active region 115. Accordingly, a series resistor is possibly added here due to a lateral current spreading. For example, the first contact element 113 may be laterally displaced with respect to the second contact region 123. For example, it is possible that the first contact element 113 horizontally overlaps with the second contact region only slightly or not at all.

FIG. 4 shows a cross-sectional view of an optoelectronic semiconductor device according to further embodiments. The optoelectronic semiconductor device illustrated in FIG. 4 is similar to that illustrated in FIG. 3. Deviating from the optoelectronic semiconductor device illustrated in FIG. 3, the first contact element 113 is directly adjacent to the first semiconductor layer 110. This means that the pillars 108 are completely removed in the region of the first contact element 113. If this variant is used, for example, in the method described in FIG. 1A, the first conductivity type semiconductor contact layer 102 may be dispensed with. For example, in this case, the first semiconductor layer 110 may be highly doped in order to achieve a contacting via the first contact element 113 here. Furthermore, it is possible that the pillars 108 are not doped or only slightly doped. For example, undoped layers have a higher absorption of light than doped ones. Accordingly, the optical properties can be improved when using undoped pillars 108.

FIG. 5 shows a schematic cross-sectional view of an optoelectronic semiconductor device according to further embodiments. Components of the optoelectronic semiconductor device 10 shown in FIG. 5 are identical or similar to those of the optoelectronic semiconductor device shown in FIG. 4. Deviating from this, a so-called Bragg mirror structure is realized within the pillars 108. The embodiment of the pillars 108 comprising a Bragg mirror structure shown in FIG. 5 can also be realized in all other embodiments. For example, the pillars 108 may comprise first and second layer regions 103, 104. A refractive index in a first layer region 103 may be different from a refractive index in the second layer region 104. Furthermore, the first layer region 103 and the second layer region 104 may be arranged periodically. A period p within which the refractive index changes periodically may satisfy the following relationship:

0.4*λ≤p≤0.6*λ, wherein λ corresponds to the wavelength within the doped semiconductor material.

The periodic change in the refractive index may be brought about for example by changing the concentration of the constituents of the respective semiconductor layers. For example, aluminum with a variable proportion may be additionally added during the production of an InGaN layer. In this way, changes in the refractive index can be achieved. In addition, a variation in the dopant concentration may be used.

The effect of the ordered photonic structure on the optical modes is intensified by the Bragg structure. As a result, the light coupling out can be increased, thereby causing a further improvement in the directionality. A combination of the embodiments of the pillars 108 with a Bragg mirror structure shown in FIG. 5 and the arrangement of the first contact element 113 in direct contact with the first semiconductor layer 110 leads to a reduction in the electrical resistance between the first contact element 113 and the first semiconductor layer 110 in comparison with a structure in which the first contact element 113 is connected to the first semiconductor layer 110 via the pillars 108. In the arrangement shown in FIG. 5, current conduction through the pillars 108 can be avoided. For example, an electrical conductivity of the pillars can be reduced by the generation of the Bragg structure. According to further embodiments, the pillars 108 may be undoped or only slightly doped.

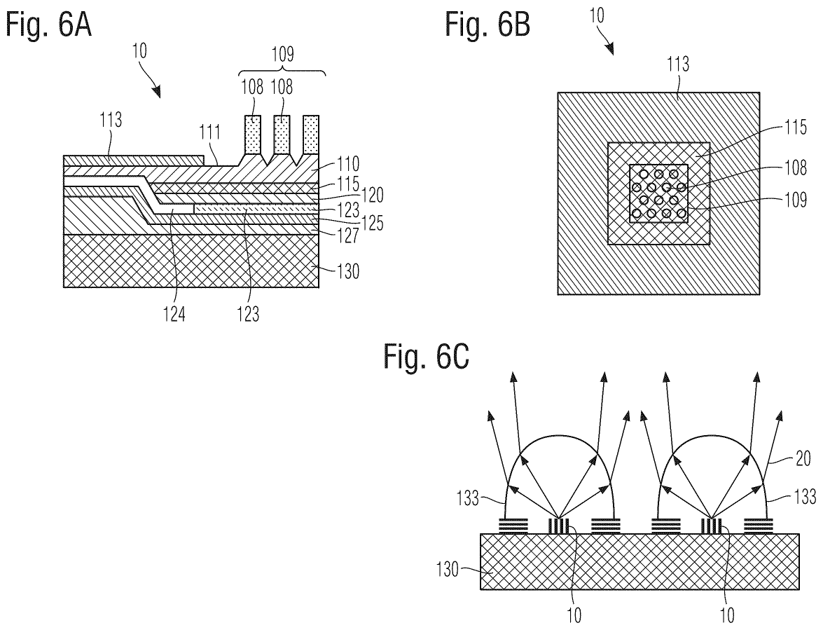

FIG. 6A shows a schematic cross-sectional view of an optoelectronic semiconductor device in which the pillars 108 are removed from a part of the optoelectronic semiconductor device 10. More precisely, it is possible that the pillars 108 extend only over a smaller area than the area of the active region 115. Accordingly, a lateral extension of the region of the pillars 108 is smaller than the lateral extension of the active region 115. Furthermore, the first contact element 113 is arranged in an edge region of the optoelectronic semiconductor device 10. For example, the first contact element 113 only slightly overlaps with the active region 115. The electromagnetic radiation generated in the active region in these regions is guided to a large extent in the waveguide formed by the active region and the surrounding layers and coupled out only to a small extent in this region. The ordered photonic structure 109 remains only in a partial region of the lateral area of the active region 115. The majority of the light coupling out takes place in the region of the ordered photonic structure 109. The emission of electromagnetic radiation from the optoelectronic semiconductor device may thus be concentrated to a very small area, for example to less than 2, 3 or 5 μm. The emitted electromagnetic radiation may, for example, be collimated better by an additional optical system, for example microlenses. For example, the pillars 108 may be doped, undoped or only slightly doped here.

FIG. 6B shows a plan view of the optoelectronic semiconductor device. As can be seen, the region in which the ordered photonic structure 109 is arranged occupies only a small region. The active region 115 has a larger lateral extension than the ordered photonic structure 109.

FIG. 6C shows an arrangement of optoelectronic semiconductor devices 10 over a common carrier substrate 130. The optoelectronic semiconductor devices 10 may be embodied as illustrated in FIG. 6A or 6B. FIG. 6C furthermore shows microlenses 133 for generating collimated or largely collimated light emission. The emitted electromagnetic radiation 20 has a very small beam cross section. Such small beam cross sections are suitable, for example, for the application in AR/VR (“augmented reality”, “virtual reality”).

According to further embodiments, the optoelectronic semiconductor device 10 shown in FIGS. 2D, 3, 4 and 5 can also be used in the arrangement shown in FIG. 6C.

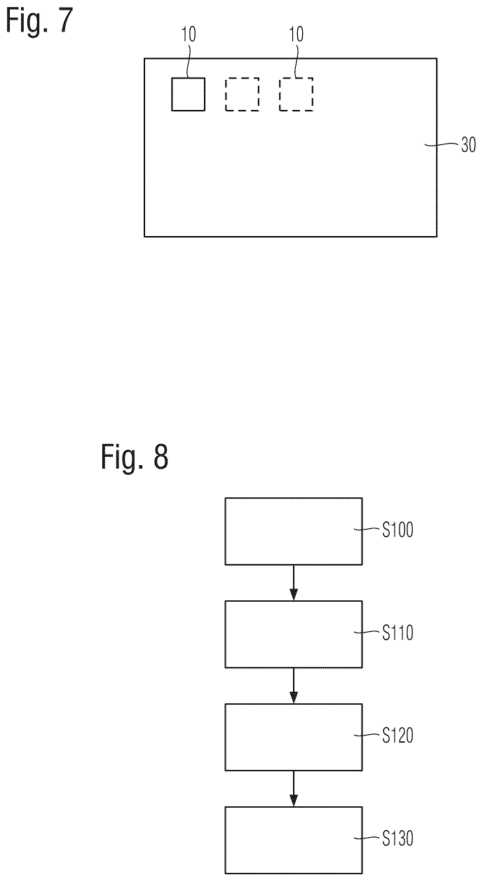

FIG. 7 shows an electronic component according to embodiments. The electronic component 30 comprises one or more optoelectronic semiconductor devices 10 as described above. For example, the electronic component may comprise an arrangement or an array of optoelectronic semiconductor devices 10. For example, the optoelectronic semiconductor devices 10 may be realized as micro-LEDs. The electronic component 30 may be, for example, an AR/VR component or a display.

FIG. 8 summarizes a method according to embodiments. A method for manufacturing an optoelectronic semiconductor device comprises patterning (S100) a masking material over a growth substrate such that a pattern of exposed surface regions is generated, and epitaxially growing (S110) a first semiconductor material over the exposed surface regions, wherein pillars are formed in a region facing the growth substrate, and a contiguous first semiconductor layer of a first conductivity type is formed in a region facing away from the growth substrate. The method further comprises forming (S120) an active region over the first semiconductor layer and the pillars, wherein the active region is adapted to emit or absorb electromagnetic radiation, and epitaxially growing (S130) a second semiconductor layer of a second conductivity type over the active region. A modal value M(d) of a distance d between centers of the exposed regions satisfies the following condition: d≤1.5*λ, wherein λ denotes the average wavelength of the electromagnetic radiation in the first semiconductor material.

By means of the production method described, an optoelectronic semiconductor device having improved light yield and improved directionality of the light emission can be achieved. In an arrangement of the optoelectronic semiconductor device in a pixel arrangement, crosstalk to adjacent pixels is reduced. Furthermore, the light outcoupling area is delimited. More precisely, for example, in the embodiment shown in FIG. 6A or 6B, a luminous area per pixel is reduced. As a result, the emitted electromagnetic radiation can be collimated better by an additional optical system, for example microlenses.

Although specific embodiments have been illustrated and described herein, persons skilled in the art will recognize that the specific embodiments shown and described can be replaced by a multiplicity of alternative and/or equivalent configurations without departing from the scope of protection of the invention. The application is intended to cover any adaptations or variations of the specific embodiments discussed herein. Therefore, the invention is limited only by the claims and the equivalents thereof.

1-21. (canceled)

22. A method for manufacturing an optoelectronic semiconductor device, the method comprising:
patterning a masking material over a growth substrate such that a pattern of exposed surface regions is generated;
epitaxially growing a first semiconductor material over the exposed surface regions, wherein pillars are formed in a region facing the growth substrate, and a contiguous first semiconductor layer of a first conductivity type is formed in a region facing away from the growth substrate;
forming an active region over the first semiconductor layer and the pillars, wherein the active region is configured to emit or absorb electromagnetic radiation;
epitaxially growing a second semiconductor layer of a second conductivity type over the active region;
applying a carrier substrate over the second semiconductor layer; and
detaching the growth substrate such that the pillars are arranged in the region of a first main surface of a resulting workpiece,
wherein a modal value M(d) of a distance d between centers of the exposed regions satisfies the following condition:
M(d)≤1.5*λ, and
wherein λ denotes an average wavelength of the electromagnetic radiation in the first semiconductor material.

23. The method according to claim 22, wherein the semiconductor material contains InGaN.

24. The method according to claim 23, wherein an In content of the semiconductor material increases with increasing distance from the growth substrate.

25. The method according to claim 22, wherein the following relationship applies to the modal value M(d):
$$0.4 * λ \leq M ( d ) \leq 0.6 * λ .$$

26. The method according to claim 22, wherein the first semiconductor material is grown such that a refractive index of a doped semiconductor material is changed.

27. The method according to claim 26, wherein the refractive index of the first semiconductor material changes periodically.

28. The method according to claim 27, wherein a period p within which the refractive index changes periodically satisfies the following relationship:
0.4*λ≤p≤0.6*λ, wherein λ corresponds to the wavelength within the first semiconductor material.

29. The method according to claim 22, further comprising removing the pillars from a part of the optoelectronic semiconductor device.

30. The method according to claim 29, wherein the pillars are removed from a region of the optoelectronic semiconductor device that does not horizontally overlap with the active region.

31. The method according to claim 29, wherein the pillars are removed from a region of the optoelectronic semiconductor device that horizontally overlaps with the active region.

32. The method according to claim 29, further comprising forming a first contact element in a region from which the pillars have been removed.

33. The method according to claim 22, further comprising applying a contact layer of the first conductivity type over the growth substrate, wherein a masking layer is applied over the contact layer and the first semiconductor material is grown over the contact layer.

34. The method according to claim 33, wherein the growth substrate is detached after applying the carrier substrate over the second semiconductor layer, further comprising removing at least a part of the contact layer after detaching the growth substrate.

35. An optoelectronic semiconductor device comprising:
a first semiconductor layer of a first conductivity type;
a second semiconductor layer of a second conductivity type;
an active region arranged between the first and the second semiconductor layer, wherein the first semiconductor layer, the active region and the second semiconductor layer are arranged forming a semiconductor layer stack and the active region is adjacent to a second main surface of the first semiconductor layer, the active region configured to emit electromagnetic radiation; and
an ordered photonic structure over a first main surface of the first semiconductor layer, wherein the ordered photonic structure is directly adjacent to the first semiconductor layer and is arranged over the active region and comprises pillars containing a semiconductor material of the first semiconductor layer, wherein a modal value M(d) of a distance d between centers of the pillars satisfies the following condition:
d≤1.5*λ, wherein λ denotes an average wavelength of the electromagnetic radiation in the semiconductor material of the first semiconductor layer.

36. The optoelectronic semiconductor device according to claim 35, wherein the semiconductor material contains InGaN.

37. The optoelectronic semiconductor device according to claim 36, wherein an In content of the semiconductor material of the pillars decreases with increasing distance from the first semiconductor layer.

38. The optoelectronic semiconductor device according to claim 35, wherein the following relationship applies to the modal value M(d) of the distance d: 0.4*Δ≤d≤0.6*λ.

39. The optoelectronic semiconductor device according to claim 35, wherein a defect density in the pillars increases with increasing distance from the first semiconductor layer.

40. The optoelectronic semiconductor device according to claim 35, wherein the pillars are removed from a part of the optoelectronic semiconductor device.

41. The optoelectronic semiconductor device according to claim 40, wherein a part of the optoelectronic semiconductor device in which pillars are present is smaller than a horizontal extension of the active region.

42. The optoelectronic semiconductor device according to claim 40, further comprising a first contact element electrically connected to the first semiconductor layer, wherein the first contact element is arranged in the part of the optoelectronic semiconductor device from which the pillars are removed.
